(19) United States
(12) Patent Application Publication
(10) Pub. No.: US 2011/0223705 A1
(43) Pub. Date: Sep. 15, 2011

(54) PROCESS FOR ASSEMBLING CAMERA MODULE

(75) Inventors: Chien-Nan Yu, Taipei (TW); Chung-Feng Tsao, Taipei (TW); Ying-Chieh Chen, Taipei (TW); Szu-Hao Lyu, Taipei (TW); Ching-Lung Jao, Taipei (TW); Hang-Kau Khor, Taipei (TW)

(73) Assignee: PRIMAX ELECTRONICS LTD., Taipei (TW)

(21) Appl. No.: 12/848,700

(22) Filed: Aug. 2, 2010

(30) Foreign Application Priority Data
Mar. 12, 2010 (TW) 099107263

(51) Int. Cl. H01L 31/18

(52) U.S. Cl. 438/65; 438/64; 257/E31.113

(57) ABSTRACT

A process for assembling a camera module is provided. Firstly, a first conductive bump and a second conductive bump are placed on a signal terminal of a substrate and a contact pad of an image sensing chip, respectively. Then, the substrate and the image sensing chip are laminated, so that the first conductive bump and the second conductive bump are combined together and the signal terminal of the substrate and the contact pad of the image sensing chip are electrically connected with each other. Then, an underfill is applied to a region between the substrate and the image sensing chip. Since the two conductive bumps are connected with each other by the assembling process, the quality of the camera module of the present invention is enhanced.

### FIELD OF THE INVENTION

The present invention relates to a process for assembling a camera module, and more particularly to a process for assembling a camera module of a portable electronic device such as a mobile phone or a personal digital assistant.

### BACKGROUND OF THE INVENTION

Conventionally, a camera module is assembled by a flip-chip packaging technology. FIG. 1 is a flowchart illustrating a process for assembling a conventional camera module. Hereinafter, a process for assembling a conventional camera module will be illustrated with reference to FIG. 1. First of all, in the step S1, a rigid-flex printed circuit board is provided. Then, in the step S2, a conductive bump is placed on an image sensing chip. In the step S3, the rigid-flex printed circuit board and the image sensing chip are laminated, so that the conductive bump and the signal terminal of the rigid-flex printed circuit board are electrically connected with each other. Then, in the step S4, an underfill is applied to a region between the rigid-flex printed circuit board and the image sensing chip. Afterwards, in the step S5, a camera lens assembly is fixed onto a second rigid printed circuit board of the rigid-flex printed circuit board via an adhesive.

FIGS. 2A, 2B, 2C and 2D schematically illustrate the steps of a process for assembling a conventional camera module. Please refer to FIG. 2A and also the step S1 of FIG. 1. The rigid-flex printed circuit board 11 comprises a first rigid printed circuit board 111, a second rigid printed circuit board 112 and a flexible printed circuit board 113. The flexible printed circuit board 113 is sandwiched between the first rigid printed circuit board 111 and the second rigid printed circuit board 112. The rigid-flex printed circuit board 11 has a perforation 114 running through the first rigid printed circuit board 111, the flexible printed circuit board 113 and the second rigid printed circuit board 112. In addition, a signal terminal 1111 is formed on a surface of the first rigid printed circuit board 111. Please refer to FIG. 2A and also the step S2 of FIG. 1. The image sensing chip 12 comprises an image sensing zone 121 and a contact pad 122. A conductive bump 13 is placed on the contact pad 122. Generally, the conductive bump 13 is made of gold (Au). As shown in FIG. 2B, the rigid-flex printed circuit board 11 and the image sensing chip 12 are laminated, so that the conductive bump 13 and the signal terminal 1111 are electrically connected with each other. As shown in FIG. 2C, an underfill 14 is applied to a region between the rigid-flex printed circuit board 11 and the image sensing chip 12. As shown in FIG. 2D, a camera lens assembly 16 is fixed onto the second rigid printed circuit board 112 so as to form a camera module 1.

The functions of respective components of the camera module 1 will be illustrated with reference to FIG. 2D. Through the conductive bump 13, the signal terminal 1111 of the rigid-flex printed circuit board 11 and the contact pad 122 of the image sensing chip 12 are electrically connected with each other. As such, the camera module 1 is conducted and enabled. The applied underfill 14 is used for sealing the region between the rigid-flex printed circuit board 11 and the image sensing chip in order to prevent the adverse environmental conditions (e.g. dust, humidity, and the like) from damaging the internal portion of the camera module 1. The camera lens assembly 16 comprises a lens 161 and a lens mount 162. The lens 161 is aligned with the perforation 114 and the image sensing zone 121. During operation of the camera module 1, a light passing through the lens 161 and the perforation 114 is received by the image sensing zone 121, and thus an image is generated.

After the conventional camera module 1 is produced by the above assembling process, a reliability test is performed to test the reliability of the conventional camera module 1. Generally, the items of the reliability test comprises a heat flow testing item, a high temperature testing item, a high humidity testing item, a high and low temperature impact testing item, a flexibility testing item, an UV exposure testing item, an anti-drop impact testing item, an automatic focus durability testing item, and the like. The reliability test found that the conventional camera module 1 may fail to pass the high and low temperature impact testing item and the anti-drop impact testing item. In other words, the capability of the conventional camera module 1 to withstand impact is usually insufficient. Therefore, there is a need of providing a camera module having strong structural strength in order to enhance the quality of the camera module.

### SUMMARY OF THE INVENTION

An object of the present invention provides a process for assembling a camera module in order to enhance the reliability of the camera module.

In accordance with an aspect of the present invention, there is provided a process for assembling a camera module. Firstly, a first conductive bump and a second conductive bump are placed on a substrate and an image sensing chip, respectively. The first conductive bump is arranged on a signal terminal of the substrate. The second conductive bump is arranged on a contact pad of the image sensing chip. Then, the substrate and the image sensing chip are laminated, so that the first conductive bump and the second conductive bump are combined together and the signal terminal and the contact pad are electrically connected with each other. Then, an underfill is applied to a region between the substrate and the image sensing chip.

In an embodiment, the process includes a step of fixing a camera lens assembly onto the substrate. The camera lens assembly includes a lens mount and a lens. The lens is aligned with an image sensing zone of the image sensing chip.

In an embodiment, the first conductive bump and the second conductive bump are conductive core bumps. The volume of the first conductive bump is larger than that of the second conductive bump. When the first conductive bump and the second conductive bump are combined together, the second conductive bump is covered by the first conductive bump, so that electrical connection between the first conductive bump and the second conductive bump is established.

In an embodiment, the substrate is a rigid-flex printed circuit board, a copper-clad laminate substrate (FR4 substrate) or a ceramic substrate.

In an embodiment, the rigid-flex printed circuit board includes a first rigid printed circuit board, a second rigid printed circuit board and a flexible printed circuit board. The flexible printed circuit board is sandwiched between the first rigid printed circuit board and the second rigid printed circuit board. The signal terminal is formed on the first rigid printed circuit board.

In an embodiment, the first conductive bump is a conductive core bump, and the second conductive bump is a conductive cavity bump. When the first conductive bump and the second conductive bump are combined together, the first conductive bump is accommodated within a cavity part of the second conductive bump to electrically connect with each other.

In an embodiment, the process further includes steps of producing a prototypal conductive block by using a ball mounting head, controlling the ball mounting head to press against the prototypal conductive block, and pulling back the ball mounting head, thereby forming the conductive cavity bump.

In an embodiment, the first conductive bump is a conductive cavity bump, and the second conductive bump is a conductive core bump. When the first conductive bump and the second conductive bump are combined together, the second conductive bump is accommodated within a cavity part of the first conductive bump to electrically connect with each other.

In an embodiment, the process further includes steps of producing a prototypal conductive block by using a ball mounting head, controlling the ball mounting head to press against the prototypal conductive block, and pulling back the ball mounting head, thereby forming the conductive cavity bump.

In an embodiment, the first conductive bump and the second conductive bump are made of gold.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a flowchart illustrating a process for assembling a conventional camera module;

FIGS. 2A, 2B, 2C and 2D schematically illustrate the steps of a process for assembling a conventional camera module;

FIG. 3 is a flowchart illustrating a process for assembling a camera module according to a first embodiment of the present invention;

FIGS. 4A, 4B, 4C and 4D schematically illustrate the steps of a process for assembling the camera module according to the first embodiment of the present invention;

FIG. 5 is a flowchart illustrating a process for assembling a camera module according to a second embodiment of the present invention;

FIGS. 6A, 6B, 6C and 6D schematically illustrate the steps of a process for assembling the camera module according to the second embodiment of the present invention; and

FIGS. 7A, 7B and 7C schematically illustrate a process for forming the conductive cavity bump of the camera module according to the second embodiment of the present invention.

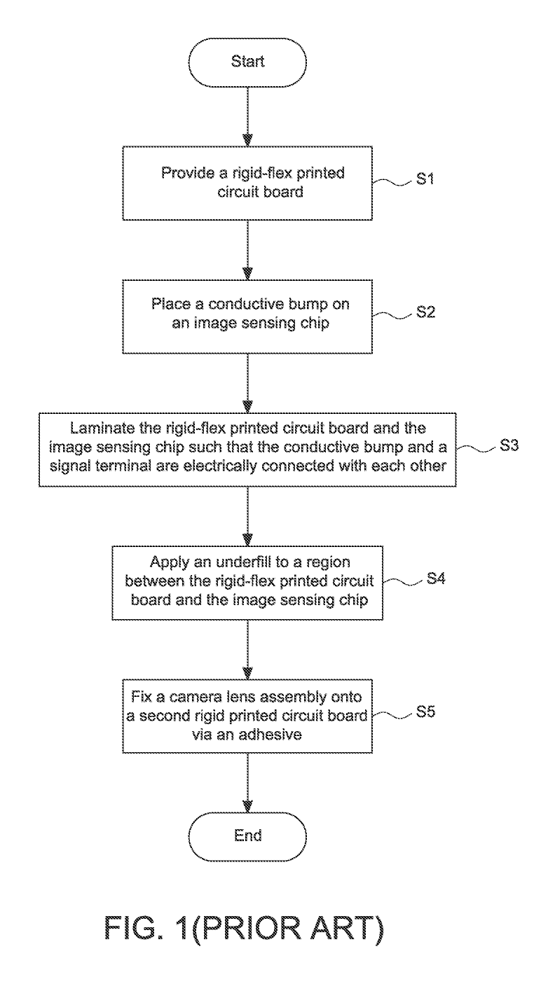

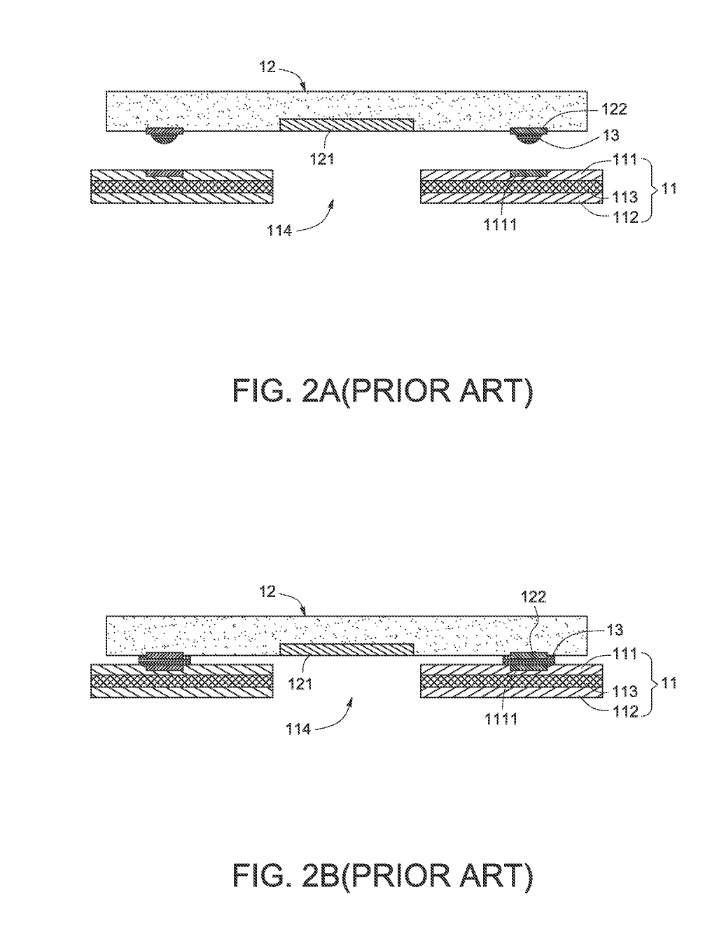

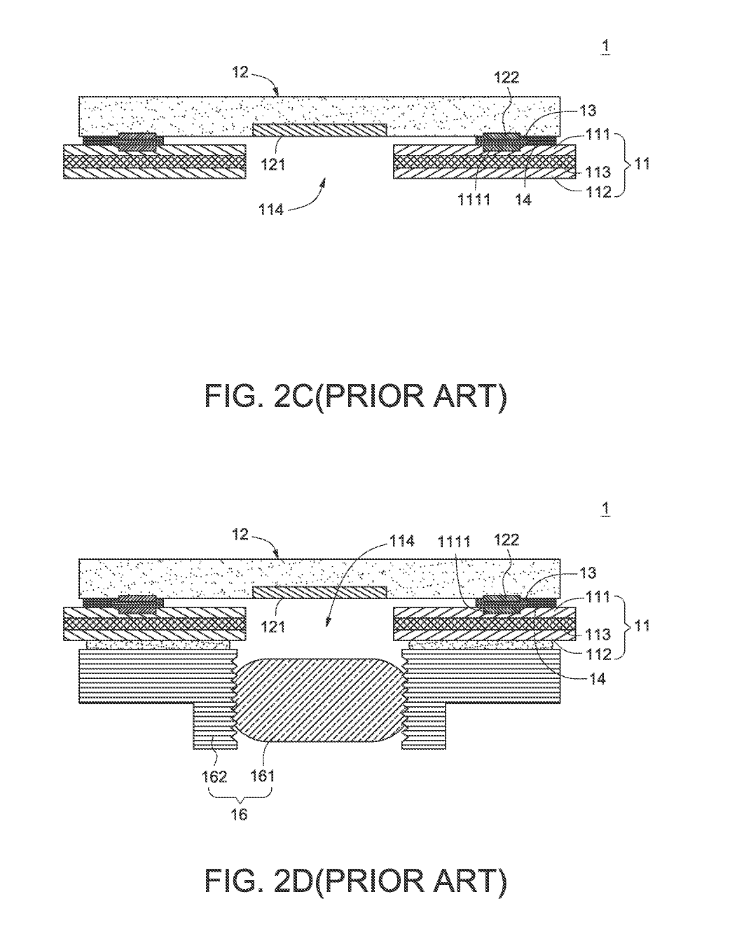

### DETAILED DESCRIPTION OF THE PREFERRED EMBODIMENT

As previously described, the conventional camera module has poor impact resistance. In order to obviate the drawbacks encountered from the prior art, the present invention provides a process for assembling a camera module by aiming at the connection between the signal terminal and the contact pad.

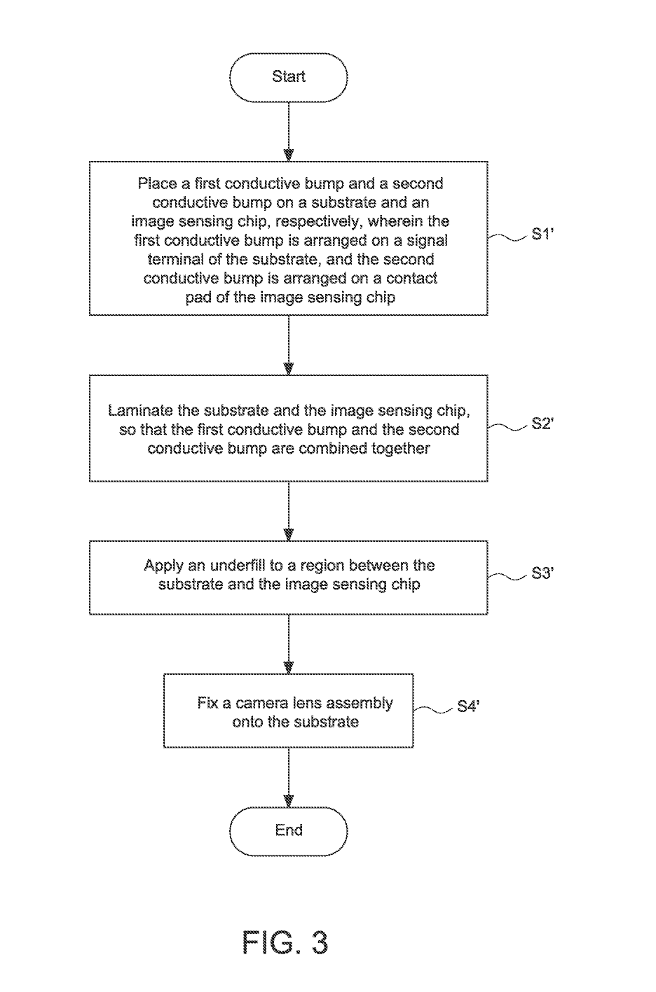

FIG. 3 is a flowchart illustrating a process for assembling a camera module according to a first embodiment of the present invention. Hereinafter, a process for assembling a camera module will be illustrated with reference to FIG. 3. First of all, in the step S1′, a first conductive bump and a second conductive bump are respectively placed on a substrate and an image sensing chip, wherein the first conductive bump is arranged on a signal terminal of the substrate, and the second conductive bump is arranged on a contact pad of the image sensing chip. In the step S2′, the substrate and the image sensing chip are laminated, so that the first conductive bump and the second conductive bump are combined together and the signal terminal and the contact pad are electrically connected with each other. Then, in the step S3′, an underfill is applied to a region between the substrate and the image sensing chip. Afterwards, in the step S4′, a camera lens assembly is fixed onto the substrate.

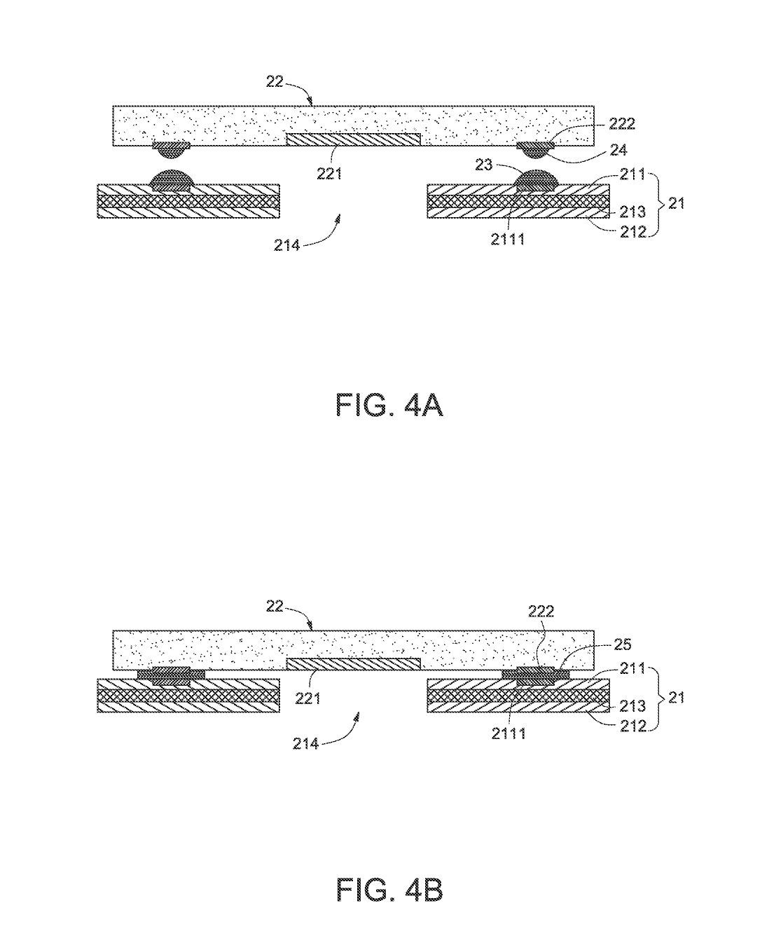

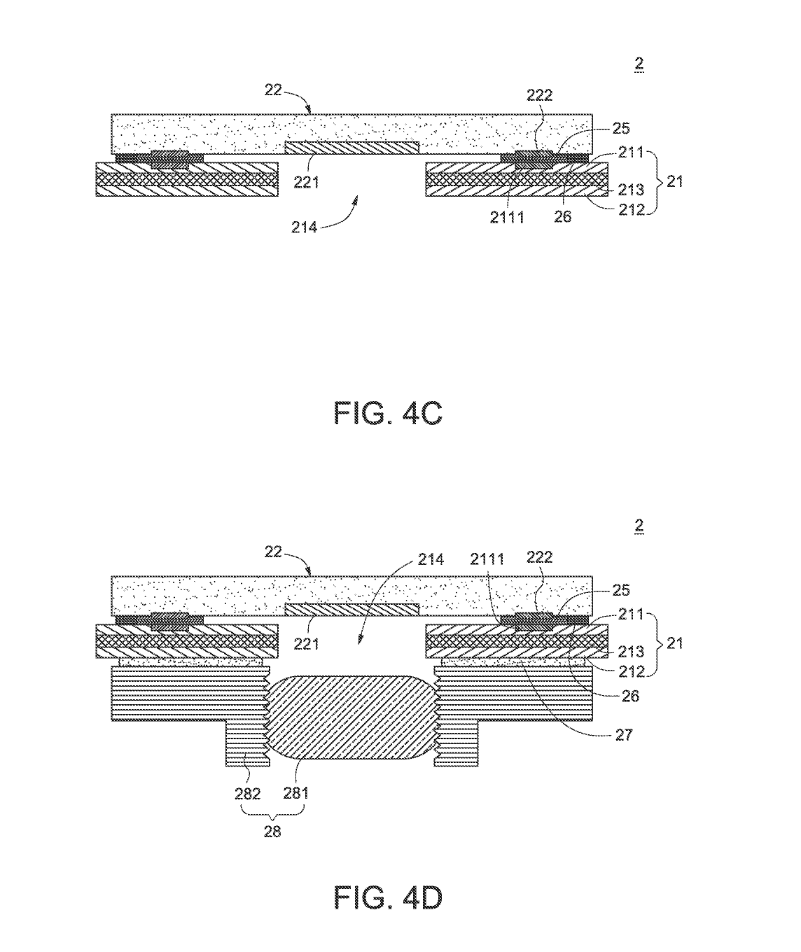

FIGS. 4A, 4B, 4C and 4D schematically illustrate the steps of a process for assembling the camera module according to the first embodiment of the present invention. An example of the substrate includes but is not limited to a rigid-flex printed circuit board, a copper-clad laminate substrate (e.g. a FR4 substrate) or a ceramic substrate. The substrate 21 of this embodiment is illustrated by referring to a rigid-flex printed circuit board. Please refer to FIG. 4A and also the step S1′ of FIG. 3. The rigid-flex printed circuit board (i.e. the substrate 21) comprises a first rigid printed circuit board 211, a second rigid printed circuit board 212 and a flexible printed circuit board 213. The flexible printed circuit board 213 is sandwiched between the first rigid printed circuit board 211 and the second rigid printed circuit board 212. A signal terminal 2111 is formed on a surface of the first rigid printed circuit board 211. The rigid-flex printed circuit board 21 has a perforation 214 running through the first rigid printed circuit board 211, the second rigid printed circuit board 212 and the flexible printed circuit board 213. A first conductive bump 23 is placed on the rigid-flex printed circuit board 21. In addition, the image sensing chip 22 comprises an image sensing zone 221 and a contact pad 222. A second conductive bump 24 is placed on the image sensing chip 22. Especially, the first conductive bump 23 is placed on the signal terminal 2111 of the rigid-flex printed circuit board 21, and the second conductive bump 24 is placed on the contact pad 222 of the image sensing chip 22. As shown in FIG. 4A, the first conductive bump 23 is a conductive core bump, and the second conductive bump 24 is also a conductive core bump. In addition, the volume of the first conductive bump 23 is larger than that of the second conductive bump 24. In this embodiment, the first conductive bump 23 and the second conductive bump 24 are made of gold.

Please refer to FIG. 4B and also the step S2′ of FIG. 3. The first conductive bump 23 of the rigid-flex printed circuit board 21 is aligned with the second conductive bump 24 of the image sensing chip 22. Then, the rigid-flex printed circuit board 21 and the image sensing chip 22 are laminated, so that the rigid-flex printed circuit board 21 and the image sensing chip 22 are combined together. Since the volume of the first conductive bump 23 is larger than that of the second conductive bump 24, the second conductive bump 24 is completely covered by the first conductive bump 23 to facilitate the alignment of the second conductive bump 24 with the first conductive bump 23. Under this circumstance, the first conductive bump 23 and the second conductive bump 24 are jointed together to form a combined conductive block 25, and the signal terminal 2111 and the contact pad 222 are electrically connected with each other.

Please refer to FIG. 4C and also the step S3′ of FIG. 3. After the rigid-flex printed circuit board 21 and the image sensing chip 22 are laminated, an underfill 26 is applied to a region between the rigid-flex printed circuit board 21 and the image sensing chip 22 in order to prevent the adverse environmental conditions (e.g. dust, humidity, and the like) from entering the internal portion of the camera module 2. As shown in FIG. 4D and also the step S4′ of FIG. 3, a camera lens assembly 28 is fixed onto the second rigid printed circuit board 212 so as to form a camera module 2. The camera lens assembly 28 comprises a lens mount 282 and a lens 281. The lens 281 is aligned with the image sensing zone 221 of the image sensing chip 22. In this embodiment, the camera lens assembly 28 is fixed onto the second rigid printed circuit board 212 via an adhesive 27. The configurations and functions of all components of the camera module 2 are similar to those illustrated in the prior art, and are not redundantly described herein.

The process for assembling the camera module according to the first embodiment of the present invention has been described above. In accordance with a key feature of the present invention, the conductive bumps 23 and 24 are respectively placed on the substrate 21 and the image sensing chip 22. By laminating the substrate 21 and the image sensing chip 22, the conductive bumps 23 and 24 of these two components are jointed together, so that the substrate 21 and the image sensing chip 22 are combined together. Since the first conductive bump 23 is placed on the signal terminal 2111 of the substrate 21, after the substrate 21 and the image sensing chip 22 are laminated and combined together, the signal terminal 2111 and the contact pad 222 are electrically connected with each other through the first conductive bump 23 and the second conductive bump 24. In other words, the joint between the first conductive bump 23 and the second conductive bump 24 can enhance the connection between the signal terminal 2111 and the contact pad 222 and improve the connecting strength between the substrate 21 and the image sensing chip 22.

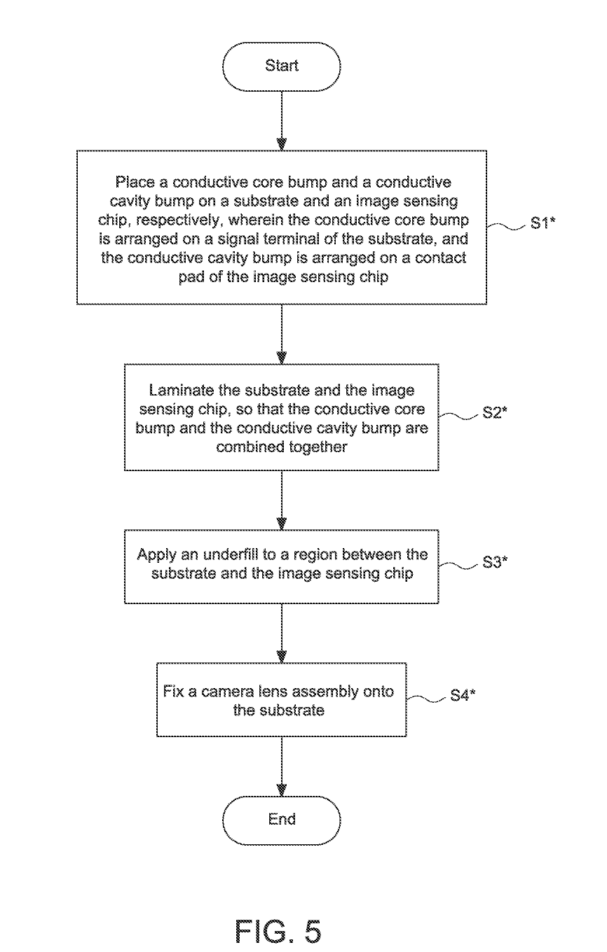

The present invention also provided a second embodiment. FIG. 5 is a flowchart illustrating a process for assembling a camera module according to a second embodiment of the present invention. In this embodiment, the first conductive bump is a conductive core bump, and the second conductive bump is a conductive cavity bump. Hereinafter, a process for assembling a camera module will be illustrated with reference to FIG. 5. First of all, in the step S1*, a conductive core bump and a conductive cavity bump are respectively placed on a substrate and an image sensing chip, wherein the conductive core bump is arranged on a signal terminal of the substrate, and the conductive cavity bump is arranged on a contact pad of the image sensing chip. In the step S2*, the substrate and the image sensing chip are laminated, so that the conductive core bump and the conductive cavity bump are combined together and the signal terminal and the contact pad are electrically connected with each other. Then, in the step S3*, an underfill is applied to a region between the substrate and the image sensing chip. Afterwards, in the step S4*, a camera lens assembly is fixed onto the substrate.

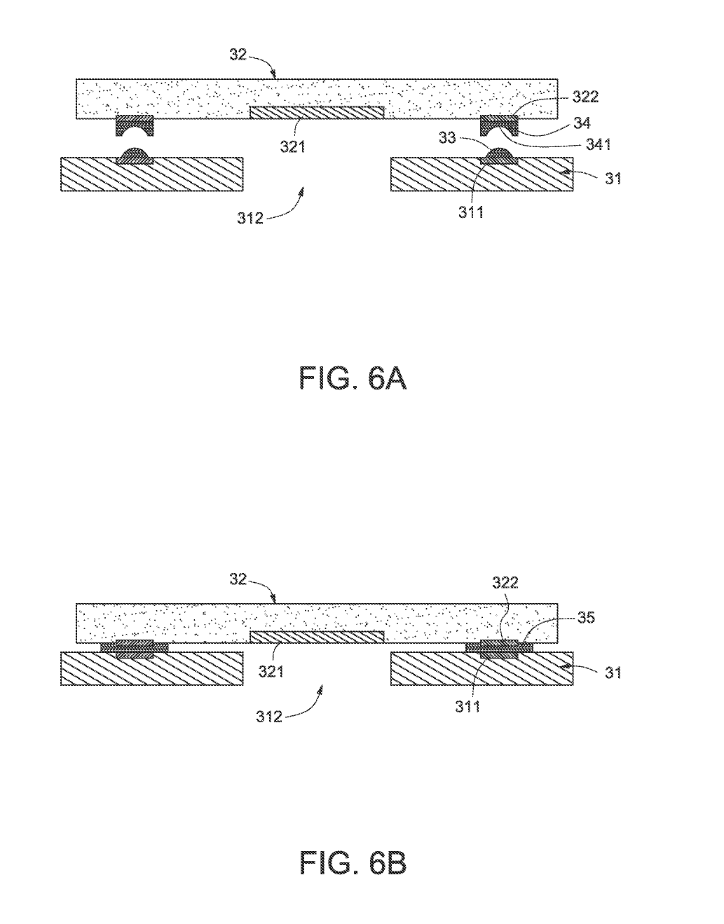

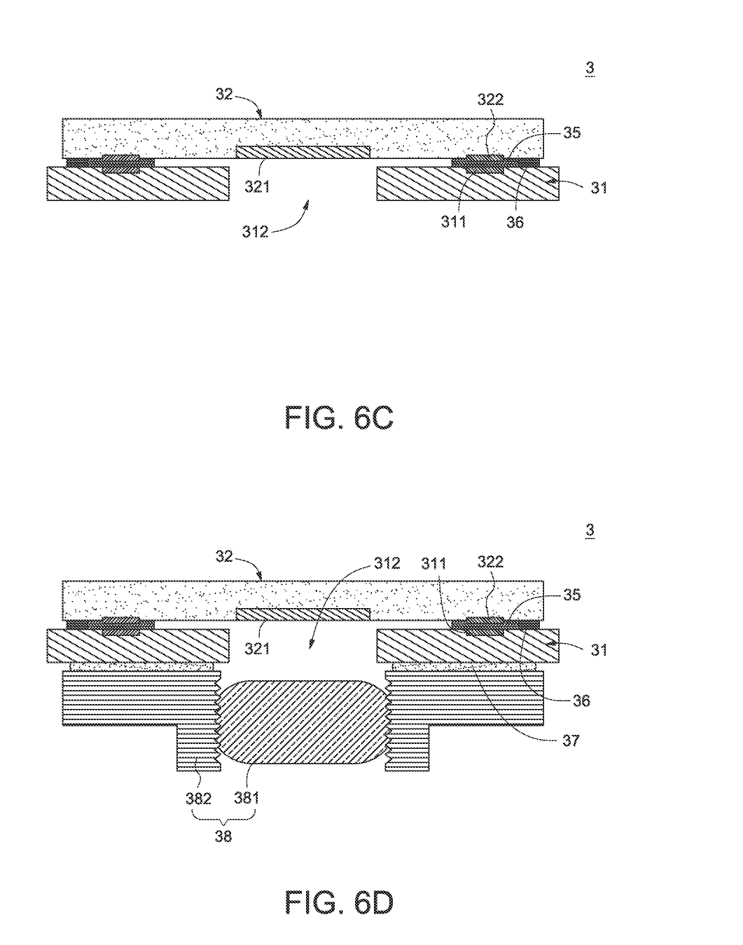

FIGS. 6A, 6B, 6C and 6D schematically illustrate the steps of a process for assembling the camera module according to the second embodiment of the present invention. The substrate 31 of this embodiment is illustrated by referring to a copper-clad laminate substrate. Please refer to FIG. 6A and also the step S1* of FIG. 5. A signal terminal 311 is formed on a surface of the substrate 31. In addition, a perforation 312 runs through the substrate 31. A conductive core bump 33 is placed on the substrate 31. In addition, the image sensing chip 32 comprises an image sensing zone 321 and a contact pad 322. A conductive cavity bump 34 is placed on the image sensing chip 32. Especially, the conductive core bump 33 is placed on the signal terminal 311 of the substrate 31, and the conductive cavity bump 34 is placed on the contact pad 322 of the image sensing chip 32. In this embodiment, the conductive core bump 33 and the conductive cavity bump 34 are made of gold.

As shown in FIG. 6A, the conductive cavity bump 34 has a cavity part 341. The conductive core bump 33 is aligned with the cavity part 341.

Please refer to FIG. 6B and also the step S2* of FIG. 5. For laminating the substrate 31 and the image sensing chip 32, the conductive core bump 33 is accommodated within the cavity part 341 of the conductive cavity bump 34. Then, the conductive core bump 33 and the conductive cavity bump 34 are jointed together to form a combined conductive block 35, so that the electrical connection between the conductive core bump 33 and the conductive cavity bump 34 is established. More especially, during the process of laminating the substrate 31 and the image sensing chip 32, the cavity part 341 of the conductive cavity bump 34 is served as an alignment reference point for facilitating the conductive core bump 33 with the conductive cavity bump 34. Please refer to FIG. 6C and also the step S3* of FIG. 5. After the substrate 31 and the image sensing chip 32 are laminated, an underfill 36 is applied to a region between the substrate 31 and the image sensing chip 32 in order to prevent the adverse environmental conditions (e.g. dust, humidity, and the like) from entering the internal portion of the camera module 3. As shown in FIG. 6D and also the step S4* of FIG. 5, a camera lens assembly 38 is fixed onto the substrate 31 so as to form a camera module 3. The camera lens assembly 38 comprises a lens mount 382 and a lens 381. The lens 381 is aligned with the image sensing zone 321 of the image sensing chip 32. In this embodiment, the camera lens assembly 38 is fixed onto the substrate 31 via an adhesive 37.

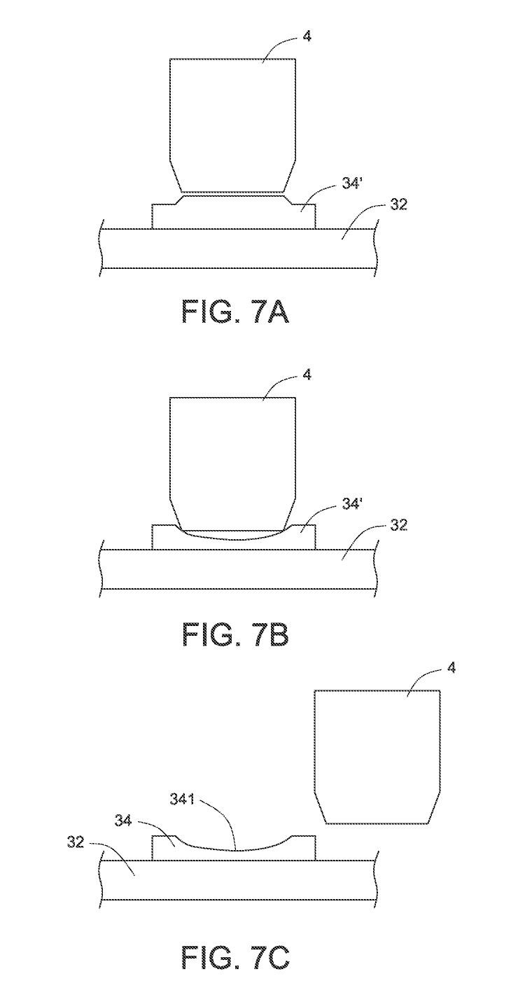

In this embodiment, before the step of placing the conductive cavity bump 34, the conductive cavity bump 34 is previously formed and then the further steps are done. A process for forming the conductive cavity bump 34 will be illustrated as follows. FIGS. 7A, 7B and 7C schematically illustrate a process for forming the conductive cavity bump of the camera module according to the second embodiment of the present invention. As shown in FIG. 7A, a prototypal conductive block 34′ is produced by using a ball mounting head 4 of a ball mounting machine according to a conductive core bump producing process. The shape of the prototypal conductive block 34′ is identical to that of the common conductive core bump. Then, as shown in FIG. 7B, the ball mounting head 4 is controlled to downwardly press against the prototypal conductive block 34′ to result in a cavity part 341. Afterwards, as shown in FIG. 7C, by controlling the ball mounting head 4 to separate from the cavity part 341, the conductive cavity bump 34 is produced.

The present invention also provides a third embodiment. In this embodiment, the first conductive bump is a conductive cavity bump, and the second conductive bump is a conductive core bump. The assembling process of the third embodiment is substantially identical to that of the second embodiment, except that the conductive core bump is placed on the image sensing chip and the conductive cavity bump is placed on the substrate. The further assembling steps are similar to those of the second embodiment, and are not redundantly described herein.

From the above description, since the first conductive bump and the second conductive bump are respectively placed on the signal terminal of the substrate and the contact pad of the image sensing chip, the adhesion between the substrate and the image sensing chip is enhanced when the substrate and the image sensing chip are laminated and combined together via two conductive bumps. Moreover, the reliability test demonstrated that, when compared with the conventional camera module, the camera module of the present invention has good results in the high and low temperature impact testing item and the anti-drop impact testing item.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A process for assembling a camera module, said process comprising steps of:
placing a first conductive bump and a second conductive bump on a substrate and an image sensing chip, respectively, wherein said first conductive bump is arranged on a signal terminal of said substrate, and said second conductive bump is arranged on a contact pad of said image sensing chip;
laminating said substrate and said image sensing chip, so that said first conductive bump and said second conductive bump are combined together and said signal terminal and said contact pad are electrically connected with each other; and
applying an underfill to a region between said substrate and said image sensing chip.

2. The process for assembling a camera module according to claim 1 further comprising a step of fixing a camera lens assembly onto said substrate, wherein said camera lens assembly comprises a lens mount and a lens, and said lens is aligned with an image sensing zone of said image sensing chip.

3. The process for assembling a camera module according to claim 1 wherein said first conductive bump and said second conductive bump are conductive core bumps, and the volume of said first conductive bump is larger than that of said second conductive bump, wherein when said first conductive bump and said second conductive bump are combined together, said second conductive bump is covered by said first conductive bump, so that electrical connection between said first conductive bump and said second conductive bump is established.

4. The process for assembling a camera module according to claim 1 wherein said substrate is a rigid-flex printed circuit board, a copper-clad laminate substrate (FR4 substrate) or a ceramic substrate.

5. The process for assembling a camera module according to claim 4 wherein said rigid-flex printed circuit board comprises a first rigid printed circuit board 1, a second rigid printed circuit board and a flexible printed circuit board, said flexible printed circuit board is sandwiched between said first rigid printed circuit board and said second rigid printed circuit board, and said signal terminal is formed on said first rigid printed circuit board.

6. The process for assembling a camera module according to claim 1 wherein said first conductive bump is a conductive core bump, and said second conductive bump is a conductive cavity bump, wherein when said first conductive bump and said second conductive bump are combined together, said first conductive bump is accommodated within a cavity part of said second conductive bump, so that electrical connection between said first conductive bump and said second conductive bump is established.

7. The process for assembling a camera module according to claim 6 further comprising steps of producing a prototypal conductive block by using a ball mounting head, controlling said ball mounting head to press against said prototypal conductive block, and pulling back said ball mounting head, thereby forming said conductive cavity bump.

8. The process for assembling a camera module according to claim 1 wherein said first conductive bump is a conductive cavity bump, and said second conductive bump is a conductive core bump, wherein when said first conductive bump and said second conductive bump are combined together, said second conductive bump is accommodated within a cavity part of said first conductive bump, so that electrical connection between said first conductive bump and said second conductive bump is established.

9. The process for assembling a camera module according to claim 8 further comprising steps of producing a prototypal conductive block by using a ball mounting head, controlling said ball mounting head to press against said prototypal conductive block, and pulling back said ball mounting head, thereby forming said conductive cavity bump.

10. The process for assembling a camera module according to claim 1 wherein said first conductive bump and said second conductive bump are made of gold.
